(19) United States
(12) Patent Application Publication
(10) Pub. No.: US 2009/0127629 A1
(43) Pub. Date: May 21, 2009

(54) Method of forming npn and pnp bipolar transistors in a CMOS process flow that allows the collectors of the bipolar transistors to be biased differently than the substrate material

(76) Inventor: Zia Alan Shafi, San Jose, CA (US)

Correspondence Address: Law Office Of Mark C. Pickering, P.O. Box 151440, San Rafael, CA, 94915-1440, US

(21) Appl. No.: 11/985,428

(22) Filed: Nov. 15, 2007

(51) Int. Cl. H01L 21/8248; H01L 27/10

(52) U.S. Cl. 257/370; 438/202; 257/E21.696; 257/E27.015

(57) ABSTRACT

NPN and PNP bipolar junction transistors are formed in a semiconductor substrate material in a double polysilicon CMOS process flow in a manner that allows the collectors of both of the npn and pnp bipolar transistors to be biased differently than the bias that is placed on the semiconductor substrate material.

### BACKGROUND OF THE INVENTION

1. Field of the Invention

The present invention relates to bipolar junction transistors and, more particularly, to a method of forming npn and pnp bipolar junction transistors in a CMOS process flow that allows the collectors of the bipolar transistors to be biased differently than the substrate material.

2. Description of the Related Art

A metal-oxide semiconductor (MOS) transistor is a well-known structure that can be fabricated as an n-channel or NMOS transistor, or as a p-channel or PMOS transistor. In addition, NMOS transistors and PMOS transistors can be fabricated as low-voltage (LV) or high-voltage (HV) transistors.

FIG. 1 shows a cross-sectional view that illustrates an example of a prior-art MOS transistor structure 100. As shown in the FIG. 1 example, MOS transistor structure 100 includes a p− semiconductor material 110, such as single-crystal silicon, and a trench isolation region 112 that is formed in p− semiconductor material 110.

As further shown in FIG. 1, MOS transistor structure 100 includes a LV PMOS transistor 114, a LV NMOS transistor 116, a HV PMOS transistor 118, and a HV NMOS transistor 120. LV PMOS transistor 114 includes a LV n-well 122 that is formed in p− semiconductor material 110, spaced-apart p-type source and drain regions 124 and 126 that are formed in LV n-well 122, and a channel region 128 that lies between the source and drain regions 124 and 126. The source and drain regions 124 and 126 include p− source and drain regions 124A and 126A, and p+ source and drain regions 124B and 126B. LV PMOS transistor 114 also includes a gate oxide region 130, and a gate 132 that sits on gate oxide region 130 over channel region 128.

LV NMOS transistor 116 includes a LV p-well 134 that is formed in p− semiconductor material 110, spaced-apart n-type source and drain regions 136 and 138 that are formed in LV p-well 134, and a channel region 140 that lies between the source and drain regions 136 and 138. The source and drain regions 136 and 138 include p− source and drain regions 136A and 138A, and p+ source and drain regions 136B and 138B. LV NMOS transistor 116 also includes a gate oxide region 142, and a gate 144 that sits on gate oxide region 142 over channel region 140.

HV PMOS transistor 118 includes a HV n-well 150 that is formed in p− semiconductor material 110, spaced-apart p-type source and drain regions 152 and 154 that are formed in HV n-well 150, and a channel region 156 that lies between the source and drain regions 152 and 154. The source and drain regions 152 and 154 include p− source and drain regions 152A and 154A, and p+ source and drain regions 152B and 154B. LV n-well 122 and HV n-well 150 have different dopant concentrations. HV PMOS transistor 118 also includes a gate oxide region 158, and a gate 160 that sits on gate oxide region 158 over channel region 156.

HV NMOS transistor 120 includes a HV p-well 164 that is formed in p− semiconductor material 110, spaced-apart n-type source and drain regions 166 and 168 that are formed in HV p-well 164, and a channel region 170 that lies between the source and drain regions 166 and 168. The source and drain regions 166 and 168 include p− source and drain regions 166A and 168A, and p+ source and drain regions 166B and 168B. LV p-well 134 and HV p-well 164 have different dopant concentrations. HV NMOS transistor 120 also includes a gate oxide region 172, and a gate 174 that sits on gate oxide region 172 over channel region 170.

FIG. 2 shows a cross-sectional view that illustrates another example of a prior-art MOS transistor structure 200. MOS transistor structure 200 is similar to MOS transistor structure 100 and, as a result, utilizes the same reference numerals to designate the elements which are common to both structures.

As shown in the FIG. 2 example, MOS transistor structure 200 differs from MOS transistor structure 100 in that MOS transistor structure 200 utilizes a LV NMOS transistor 210 in lieu of LV NMOS transistor 116, and a HV NMOS transistor 212 in lieu of HV NMOS transistor 120. LV NMOS transistor 210 and HV NMOS transistor 212 are similar to LV NMOS transistor 116 and HV NMOS transistor 120, respectively, and as a result utilize the same reference numerals to designate the elements which are common to both structures.

As shown in FIG. 2, LV NMOS transistor 210 differs from LV NMOS transistor 116 is that LV NMOS transistor 210 also includes a deep n− well 214 that lies between p− semiconductor material 110 and LV p-well 134. Similarly, HV NMOS transistor 212 differs from HV NMOS transistor 120 in that HV NMOS transistor 212 includes a deep n− well 216 that lies between p− semiconductor material 110 and HV p-well 164. In operation, deep n− well 214 allows LV p-well 134 to be biased differently than p-semiconductor material 110, while deep n− well 216 allows HV p-well 164 to be biased differently than p− semiconductor material 110.

A BiCMOS transistor structure is a structure that includes NMOS transistors, PMOS transistors, and bipolar junction transistors. FIG. 3 shows a cross-sectional view that illustrates an example of a prior-art BiCMOS transistor structure 300. As shown in FIG. 3, BiCMOS transistor structure 300 is similar to MOS transistor structure 200 and, as a result, utilizes the same reference numerals to designate the elements which are common to both structures.

As shown in the FIG. 3 example, BiCMOS transistor structure 300 differs from MOS transistor structure 200 in that BiCMOS transistor structure 300 also includes an npn bipolar transistor 310 and a pnp bipolar transistor 312. NPN transistor 310 includes a deep n− well 314 that is formed in p− semiconductor material 110, and a LV p-well 316 that is formed in semiconductor material 110 to touch and lie above deep n− well 314.

As further shown in FIG. 3, NPN transistor 310 also includes a p+ region 320 and an n+ region 322 that are spaced-apart and formed in LV p-well 316. NPN transistor 310 further includes a LV n-well 324 that is formed in semiconductor material 110 to touch and lie above deep n− well 314, and an n+ region 326 that is formed in LV n-well 324. In operation, deep n− well 314, LV n-well 324, and n+ region 326 function as the collector, LV p-well 316 functions as the base, p+ region 320 functions as the base contact, and n+ region 322 functions as the emitter.

PNP transistor 312, in turn, includes a LV n-well 330 that is formed in p− semiconductor material 110, along with an n+ region 332 and a p+ region 334 that are spaced apart and formed in LV n-well 330. PNP transistor 312 further includes a LV p-well 336 that is formed in p− semiconductor material 110, and a p+ region 338 that is formed in LV p-well 336. In operation, p− semiconductor material 110, LV p-well 336, and p+ region 338 function as the collector, LV n-well 330 functions as the base, n+ region 332 functions as the base contact, and p+ region 334 functions as the emitter.

FIGS. 4A-4P show a series of cross-sectional views that illustrate an example of a prior-art method 400 of forming a BiCMOS transistor structure. As shown in FIG. 4A, method 400 utilizes a conventionally-formed p− semiconductor material 410, such as single-crystal silicon, which has been conventionally processed to include a trench isolation region 412.

As further shown in FIG. 4A, method 400 begins by forming and patterning a mask 414 on the top surface of p− semiconductor material 410. Following this, the exposed regions of semiconductor material 410 are implanted to form a number of deep n− wells 416, including deep n− well 416A, deep n− well 416B, and deep n− well 416C. The deep n− wells 416A, 416B, and 416C, which have substantially equal dopant concentrations, can be spaced apart from each other as shown in FIG. 4A, or can be formed as a contiguous region that touch each other. Mask 414 is then removed.

Once mask 414 has been removed, as shown in FIG. 4B, a mask 420 is formed and patterned on the top surface of p− semiconductor material 410. Following this, the exposed regions of p− semiconductor material 410 are implanted to form a HV p-well 422 that corresponds with the to-be-formed HV NMOS transistor. Mask 420 is then removed.

After mask 420 has been removed, as shown in FIG. 4C, a mask 424 is formed and patterned on the top surface of p− semiconductor material 410. Following this, the exposed regions of p− semiconductor material 410 are implanted to form a HV n-well 426 that corresponds with the to-be-formed HV PMOS transistor. Mask 424 is then removed.

Next, as shown in FIG. 4D, a thick layer of gate oxide 430 is formed on the top surface of p− semiconductor material 410, followed by the formation of a first polysilicon layer 432. After first polysilicon layer 432 has been formed, a mask 434 is formed and patterned on the top surface of first polysilicon layer 432. In addition, as shown, the thermal conditions of the processing cause the deep n-wells 416 to become larger due to diffusion.

Following this, as shown in FIG. 4E, the exposed regions of first polysilicon layer 432 and underlying gate oxide layer 430 are sequentially removed so that first polysilicon layer 432 lies over only the high voltage wells 422 and 426. After gate oxide layer 430 has been removed, mask 434 is then removed.

Next, as shown in FIG. 4F, a mask 436 is formed and patterned on the top surface of p− semiconductor material 410 and first polysilicon layer 432. After mask 436 has been formed, the exposed regions of p− semiconductor material 410 are implanted to form a number of LV n-wells 440. The LV n-wells, which have substantially equal dopant concentrations, include a LV n-well of the to-be-formed LV PMOS transistor, a LV n-well of the base region of the to-be-formed pnp transistor, and a LV n-well of the collector region of the to-be-formed npn transistor. Mask 436 is then removed.

After mask 436 has been removed, as shown in FIG. 4G, a mask 442 is formed and patterned on the top surface of p− semiconductor material 410 and first polysilicon layer 432. Following this, the exposed regions of p− semiconductor material 410 are implanted to form a number of LV p-wells 444. The LV p-wells 444, which have substantially equal dopant concentrations, include a LV p-well 444-1 of the to-be-formed LV NMOS transistor, a LV p-well 444-2 of the base region of the to-be-formed npn transistor, and a LV p-well 444-3 of the collector region of the to-be-formed pnp transistor. Mask 442 is then removed.

Next, as shown in FIG. 4H, a thin layer of gate oxide 446 is formed on the top surface of p− semiconductor material 410 and first polysilicon layer 432, followed by the formation of a second polysilicon layer 448. After second polysilicon layer 448 has been formed, a mask 450 is formed and patterned on the top surface of second polysilicon layer 448.

Following this, as shown in FIG. 4I, the exposed regions of second polysilicon layer 448 and underlying gate oxide layer 446 are sequentially removed from the top surface of first polysilicon layer 432. (Second polysilicon layer 448 and gate oxide layer 446 can be overetched to produce the result shown in FIG. 4I.) Mask 450 is then removed.

Once mask 450 has been removed, as shown in FIG. 4J, a mask 452 is formed and patterned over the top surface of the first and second polysilicon layers 432 and 448. After this, as shown in FIG. 4K, the exposed regions of the first and second polysilicon layers 432 and 448 are etched to form a number of HV gates 454 and a number of LV gates 456. Mask 452 is then removed.

Next, as shown in FIG. 4L, a mask 460 is formed and patterned over the top surface of p− semiconductor material 410. Following this, the exposed regions of HV p-well 422 are implanted to form n− source and drain regions 462S and 462D. In addition, the exposed regions of LV p-well 444 that corresponds with the to-be-formed LV NMOS transistor are also implanted to form n− source and drain regions 464S and 464D. Mask 460 is then removed.

As shown in FIG. 4M, once mask 460 has been removed, a mask 466 is formed and patterned over the top surface of p− semiconductor material 410. Following this, the exposed regions of HV n-well 426 are implanted to form p− source and drain regions 470S and 470D. In addition, the exposed regions of LV n-well 440 that corresponds with the to-be-formed LV PMOS transistor are implanted to form p− source and drain regions 472S and 472D. Mask 466 is then removed.

Once mask 466 has been removed, a layer of isolation material, such as oxide, is deposited over the top surface of p− semiconductor material 410. Following this, as shown in FIG. 4N, the layer of isolation material is anisotropically etched to form side wall spacers 474 around the HV gates 454 and the LV gates 456.

After the side wall spacers 474 have been formed, a mask 476 is formed and patterned over the top surface of p− semiconductor material 410. After this, the exposed regions are implanted to form n+ source and drain regions 480S and 480D in the n− source and drain regions 462S and 462D and the HV p-well 422, and n+ source and drain regions 482S and 482D in the n− source and drain regions 464S and 464D and the LV p-well 444.

In addition, the implant also forms an n+ base contact region 484B in the LV n-well 440 that corresponds with the pnp transistor, an n+ collector region 484C in the LV n-well 440 that corresponds with the npn transistor, and an n+ emitter region 484E in the LV p-well 444 that corresponds with the npn transistor. Mask 476 is then removed.

Once mask 476 has been removed, as shown in FIG. 4O, a mask 486 is formed and patterned over the top surface of p− semiconductor material 410. After this, the exposed regions are implanted to form p+ source and drain regions 488S and 488D in the p− source and drain regions 470S and 470D and the HV n-well 426, and p+ source and drain regions 490S and 490D in the p− source and drain regions 472S and 472D and the LV n-well 440.

In addition, the implant also forms a p+ base contact region 492B in the LV p-well 444 that corresponds with the npn transistor, a p+ collector region 492C in the LV p-well 444 that corresponds with the pnp transistor, and a p+ emitter region 492E in the LV n-well 440 that corresponds with the pnp transistor. Mask 486 is then removed.

After the implant, mask 486 is removed to form the BiCMOS transistor structure shown in FIG. 4P. Following this, the method continues with conventional steps. As illustrated, the BiCMOS transistor shown in FIG. 4P is identical to the BiCMOS transistor structure 300. (The HV NMOS and PMOS transistors can alternately be formed with ballast regions in a conventional manner.)

One of the advantages of method 400 is that the npn and pnp transistors (e.g., transistors 310 and 312) can be formed utilizing the same process steps as are used to form the LV MOS transistors (e.g., transistors 114 and 116). However, one of the disadvantages of the pnp transistor (e.g., transistor 312) is that semiconductor material 410 functions as part of the collector. As a result, it is not possible to bias the collector of the pnp transistor differently from semiconductor material 410. Thus, there is a need for a method of forming pnp transistors in a CMOS process flow that allows the collector and semiconductor material to be biased differently.

### BRIEF DESCRIPTION OF THE DRAWINGS

FIG. 1 is a cross-sectional view illustrating an example of a prior-art MOS transistor structure 100.

FIG. 2 is a cross-sectional view illustrating another example of a prior-art MOS transistor structure 200.

FIG. 3 is a cross-sectional view illustrating an example of a prior-art BiCMOS transistor structure 300.

FIGS. 4A-4P are a series of cross-sectional views illustrating an example of a prior-art method 400 of forming a BiCMOS transistor structure.

FIG. 5 is a cross-sectional view illustrating an example of a BiCMOS transistor structure 500 in accordance with the present invention.

FIGS. 6A-6F are cross-sectional views illustrating an example of a method 600 of forming a BiCMOS transistor structure in accordance with the present invention.

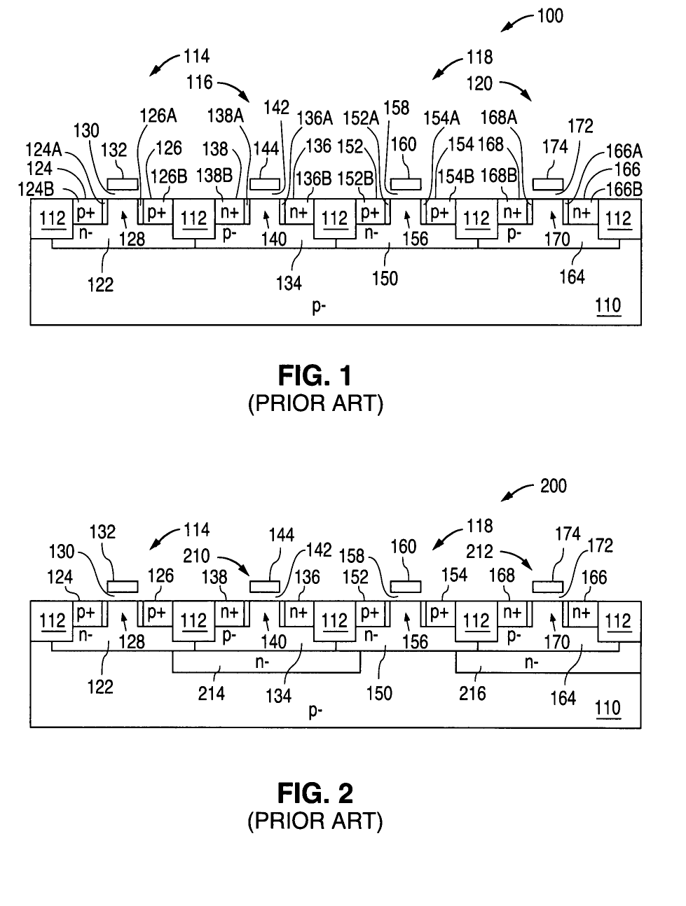

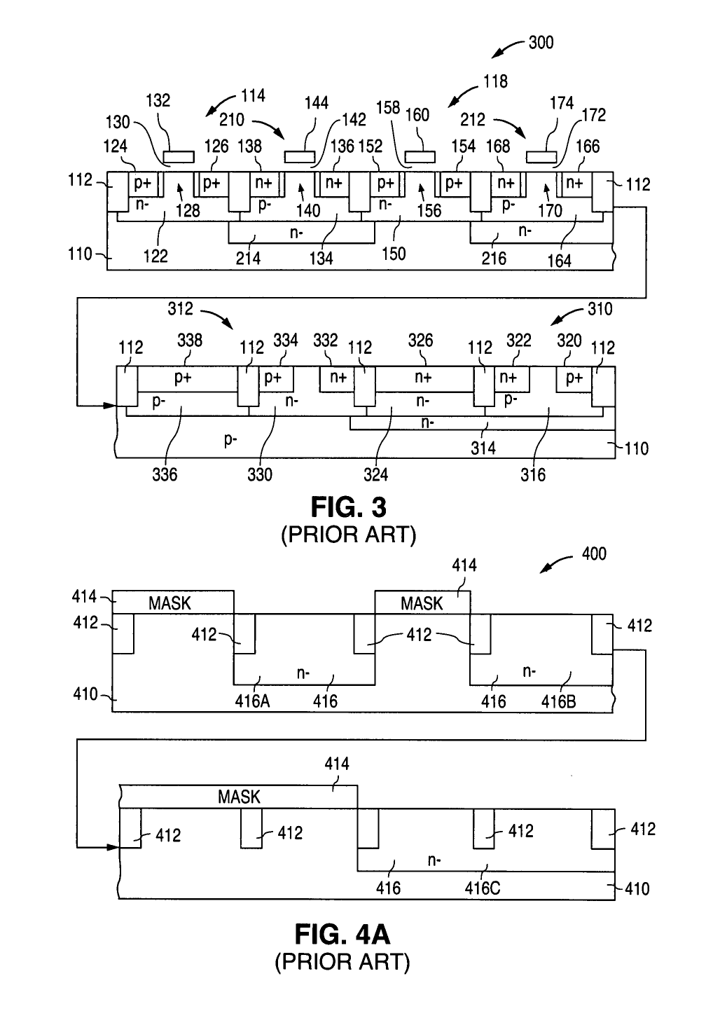

### DETAILED DESCRIPTION OF THE INVENTION

FIG. 5 shows a cross-sectional view that illustrates an example of a BiCMOS transistor structure 500 in accordance with the present invention. As described in greater detail below, BiCMOS transistor structure 500 is formed in a process that allows the collector and semiconductor material to be biased differently.

As shown in FIG. 5, BICMOS transistor structure 500 is similar to BICMOS transistor structure 300 and, as a result, utilizes the same reference numerals to designate the elements which are common to both structures. BiCMOS transistor structure 500 differs from BiCMOS transistor structure 300 in that BiCMOS transistor structure 500 utilizes a pnp transistor 512 in lieu of pnp transistor 312.

PNP transistor 512, in turn, is similar to pnp transistor 312 and, as a result, utilizes the same reference numerals to designate the structures which are common to both transistors. As further shown in FIG. 5, pnp transistor 512 differs from pnp transistor 312 in that pnp transistor 512 utilizes a HV p-well 514 in lieu of LV n-well 330, and further includes a LV n-well 516 that contacts HV p-well 514, and a deep n− well 518 that lies below and touches LV p-well 336 and HV p-well 514. N+ base contact region 332 and p+ emitter 334 are then formed in LV n-well 516. In the present example, no n-type region lies between the deep n− wells 314 and 518 and a region of a bottom side 110B of p− semiconductor material 110 that lies directly below.

LV PMOS transistor 114, LV NMOS transistor 210, HV PMOS transistor 118, HV NMOS transistor 212, npn transistor 310, and pnp transistor 512 operate in a conventional fashion. However, in accordance with the present invention, the collector of PNP transistor 512 is separated from p− semiconductor material 110 and, as a result, can be biased with a different voltage than the voltage placed on p− semiconductor material 110.

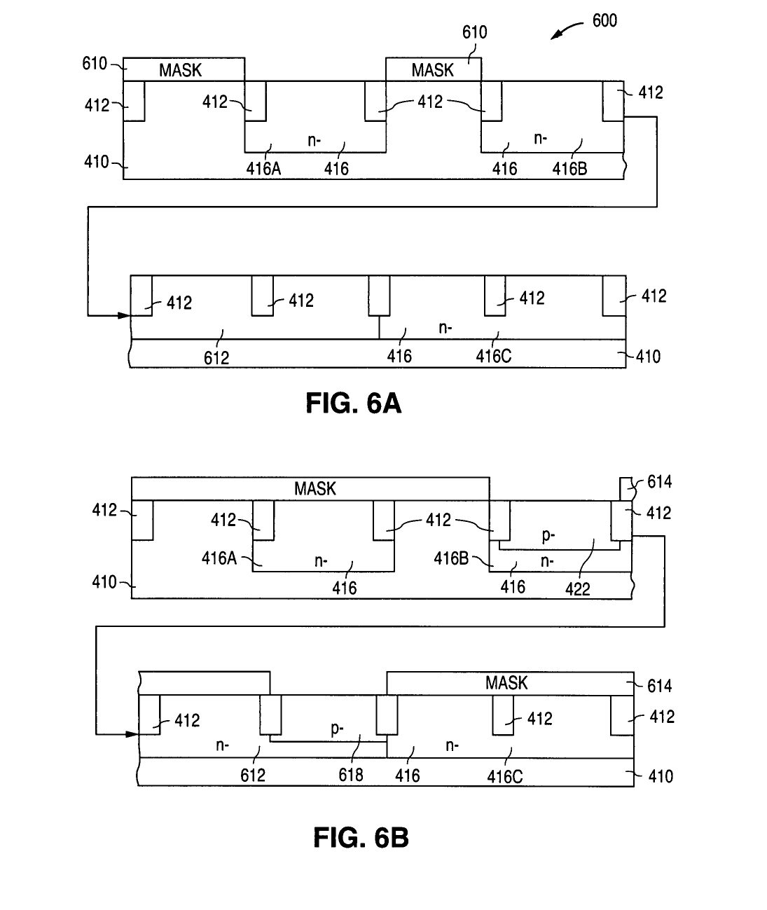

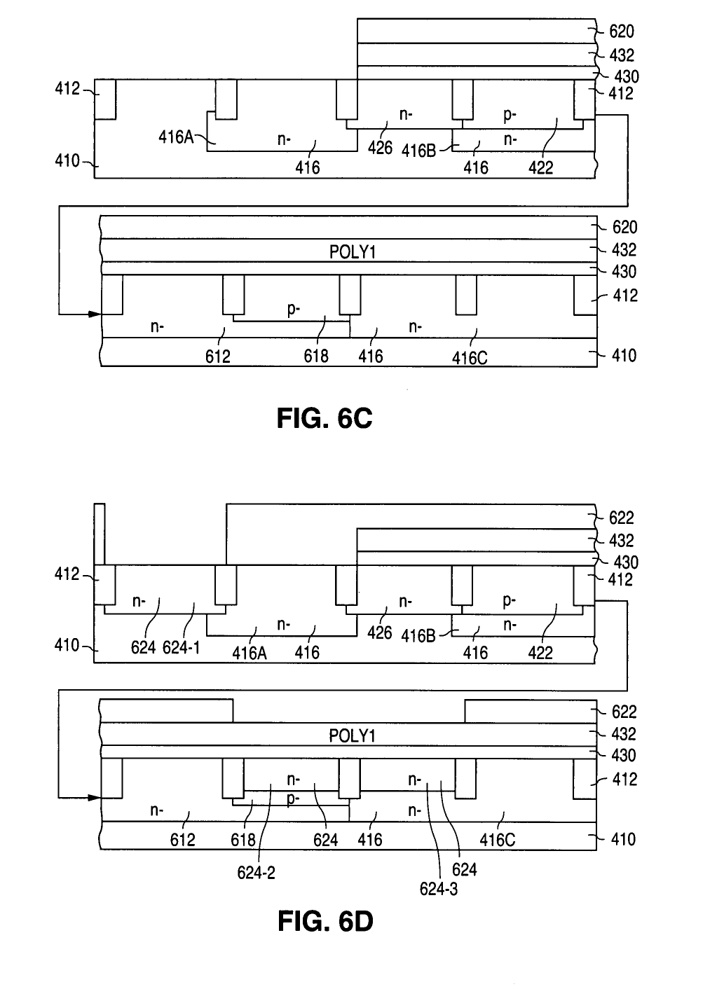

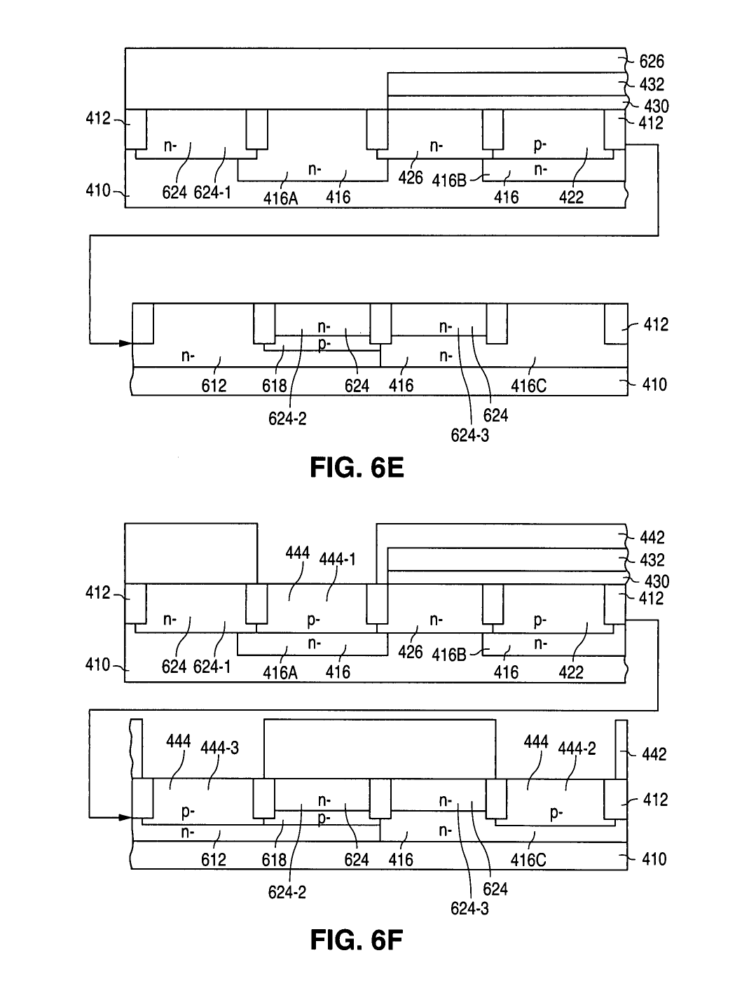

FIGS. 6A-6F show views that illustrate an example of a method 600 of forming a BiCMOS structure in accordance with the present invention. Method 600 is similar to method 400 and, as a result, utilizes the same reference numerals to designate the elements that are common to both methods. As shown in FIG. 6A, method 600 utilizes p− semiconductor material 410 which has been conventionally processed to include trench isolation region 412.

As further shown in FIG. 6A, method 600 initially differs from method 400 in that method 600 begins by forming and patterning a mask 610 in lieu of mask 414 on the top surface of p− semiconductor material 410. Mask 610 is different from mask 414 in that mask 610 exposes the region of p− semiconductor material 410 that corresponds with the to-be-formed pnp transistor. Following this, the exposed regions of semiconductor material 410 are implanted to form the deep n− wells 416 as before, along with a deep n− well 612 that corresponds with the to-be-formed pnp transistor.

The deep n− wells 416A, 416B, 416C, and 612, which have substantially equal dopant concentrations, can be spaced apart from each other, formed as a contiguous region that touch each other, or formed in any combination thereof (some touching and some spaced apart). For example, deep n− well 416C and deep n− well 612 can be considered to be a single contiguous region that is spaced apart from deep n− wells 416A and 416B, or deep n− wells 416B, 416C, and 612 can be considered to be a single contiguous region that is spaced apart from deep n− well 416A. Mask 610 is then removed.

As shown in FIG. 6B, once mask 610 has been removed, method 600 next forms and patterns a mask 614 in lieu of mask 420 on the top surface of p− semiconductor material 410. Mask 614 is different from mask 420 in that mask 614 exposes the base region of the to-be-formed pnp transistor. Following this, the exposed regions of semiconductor material 410 are implanted to form the HV p-well 422 as before, along with a HV p-well 618 that corresponds with the to-be-formed pnp transistor. The HV p-wells 422 and 618 have substantially equal dopant concentrations. Mask 614 is then removed.

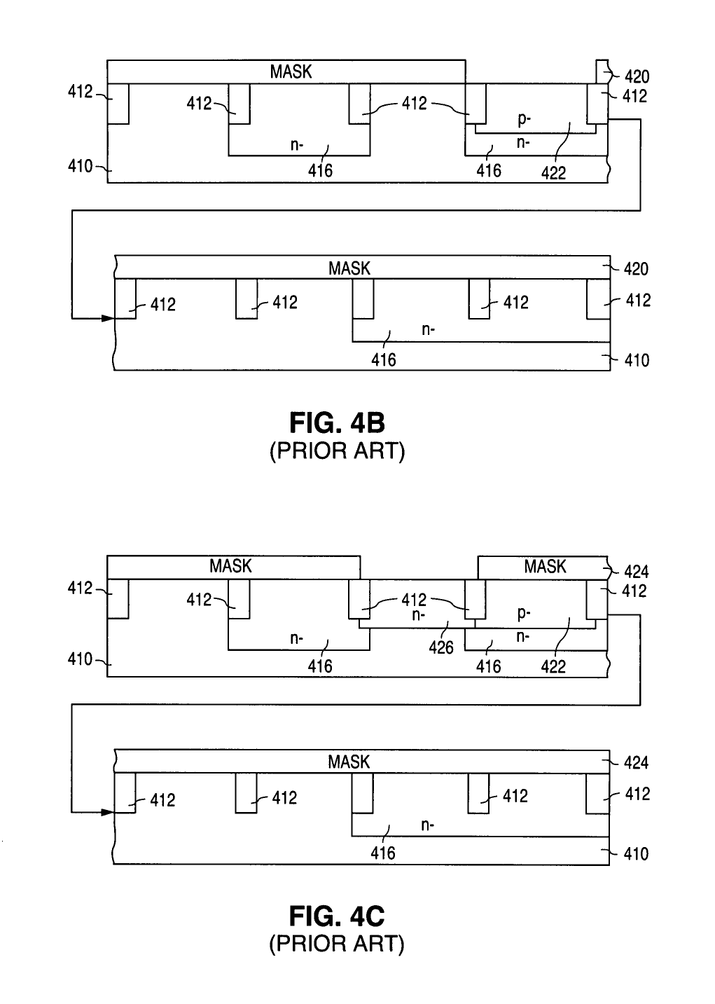

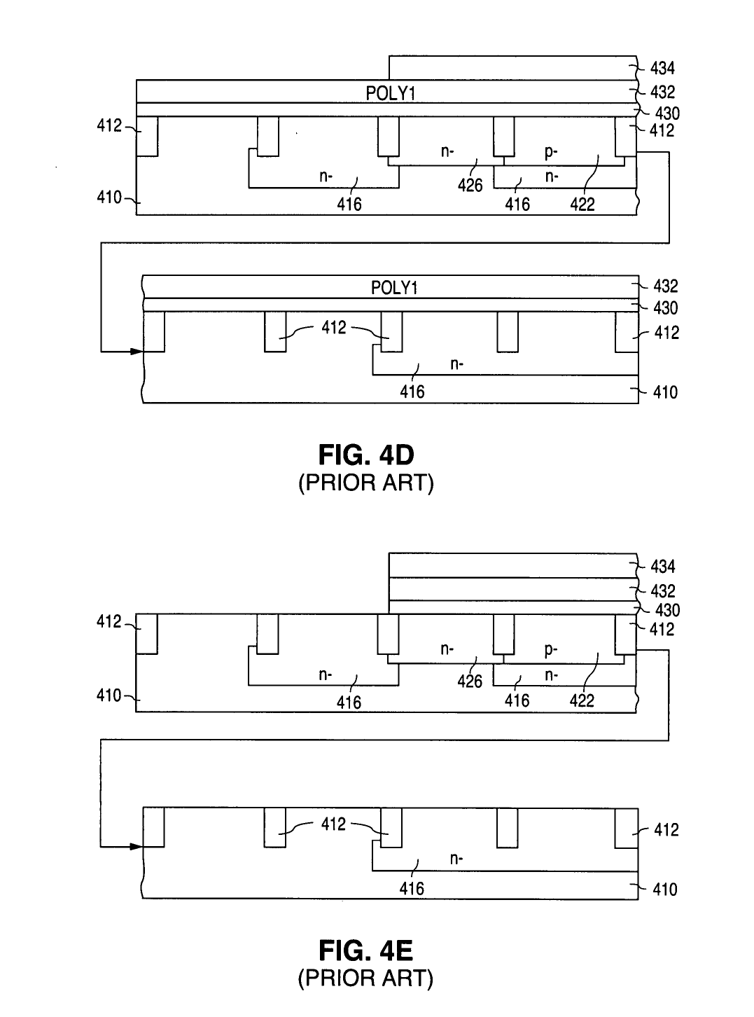

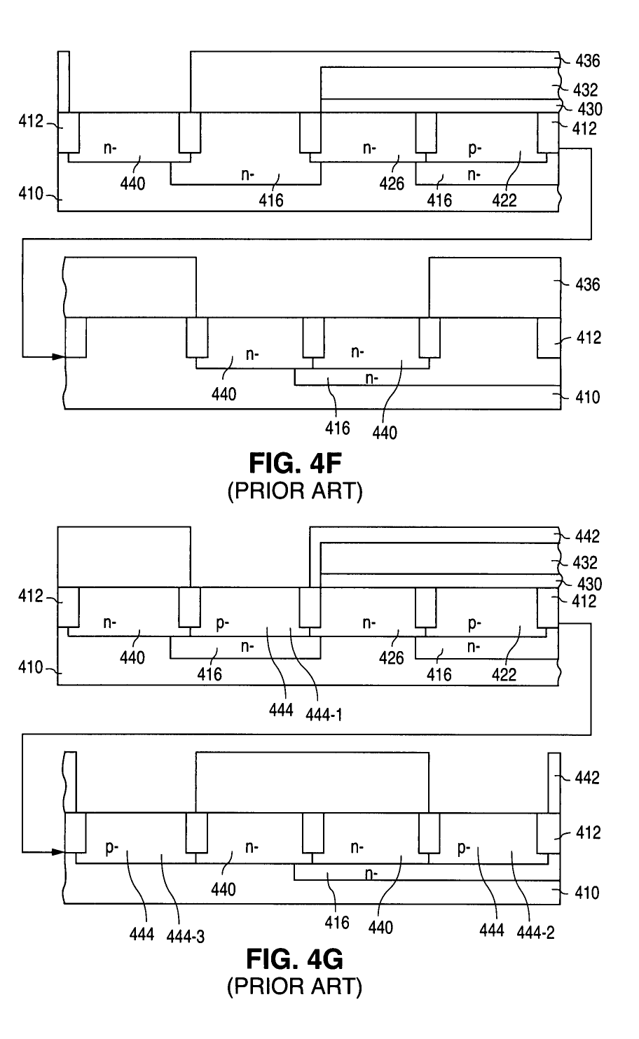

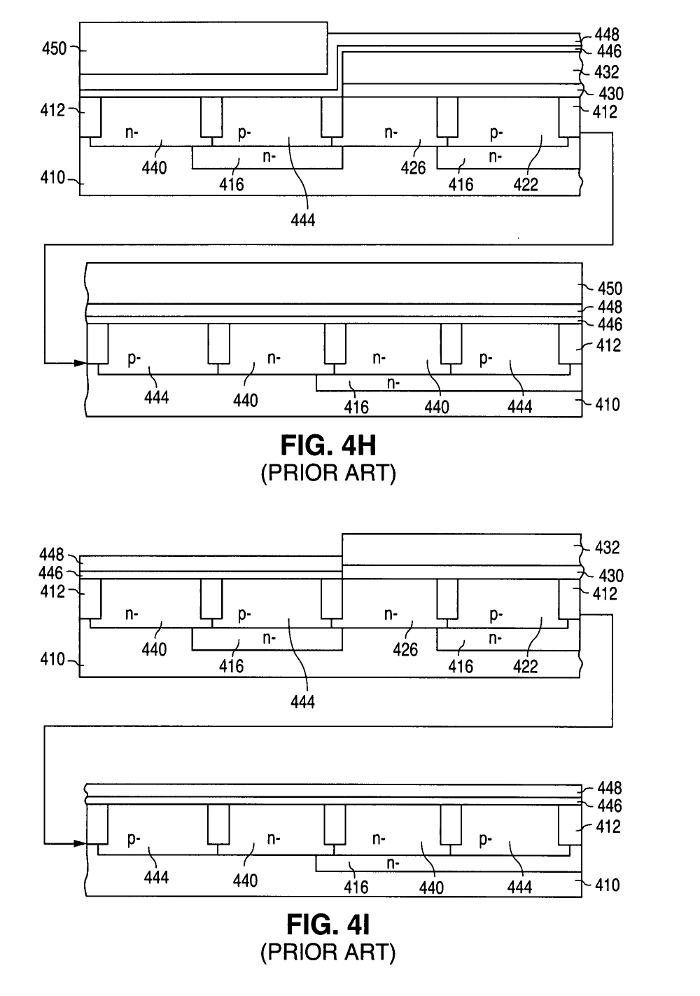

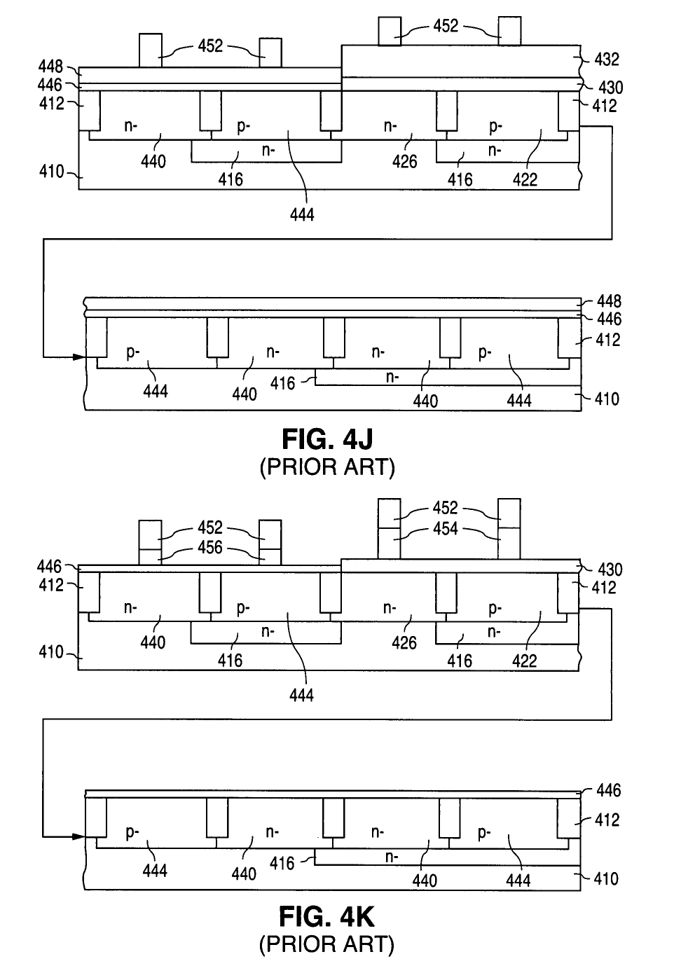

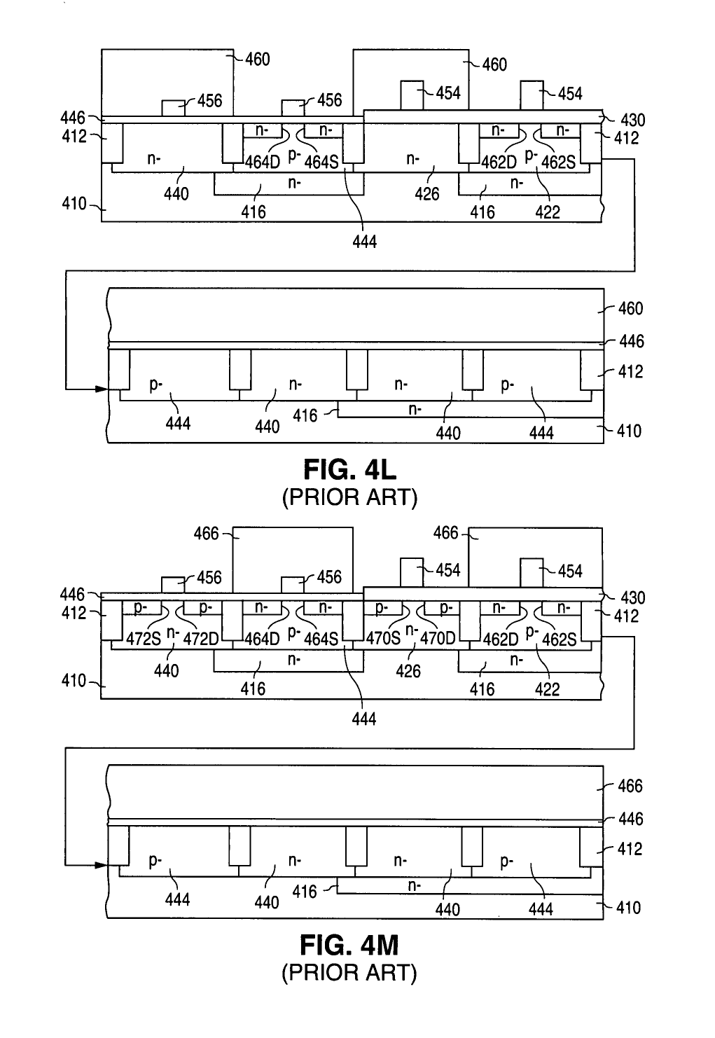

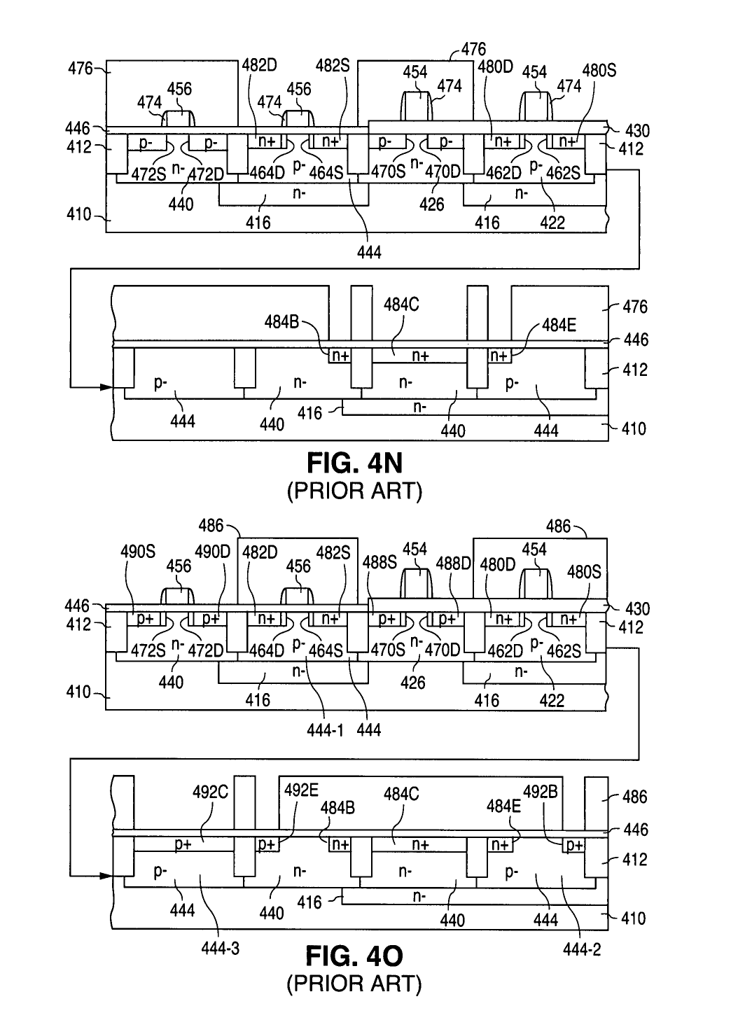

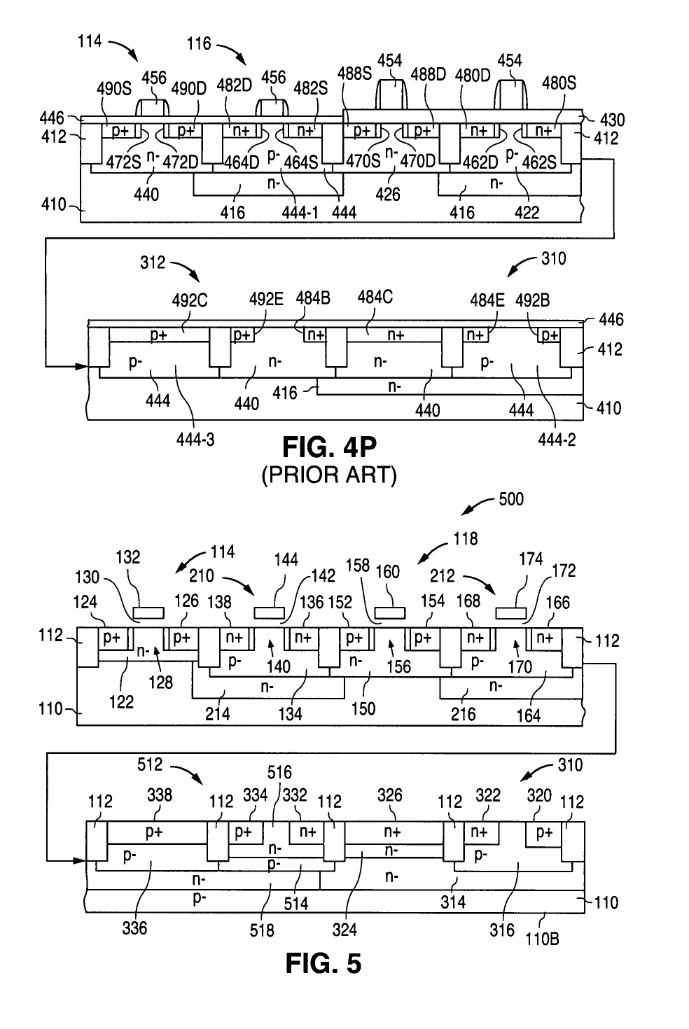

Once mask 614 has been removed, method 600 next forms mask 424 as described above, and follows the same process as method 400 up through the formation of first polysilicon layer 432 in FIG. 4D. Following this, as shown in FIG. 6C, method 600 differs from method 400 in that method 600 forms and patterns a mask 620 on the top surface of first polysilicon layer 432 in lieu of mask 434. Mask 620 differs from mask 434 in that mask 620 also covers the HV p-well 618 of the to-be-formed pnp bipolar transistor. In the present example, mask 620 additionally covers the deep n− wells 416C and 612.

After mask 620 has been formed, the exposed regions of first polysilicon layer 432 and underlying gate oxide layer 430 are sequentially removed so that first polysilicon layer 432 lies over the HV wells 422 and 426 as before, but also lies over HV p-well 618 (along with the deep n− wells 416C and 612). After gate oxide layer 430 has been removed, mask 620 is then removed.

Next, as shown in FIG. 6D, a mask 622 is formed and patterned on the top surface of p− semiconductor material 410 and first polysilicon layer 432. After mask 622 has been formed, the exposed regions of p− semiconductor material 410 are implanted to form a number of LV n-wells 624. The LV n-wells 624, which have substantially equal dopant concentrations, include a LV n-well 624-1 of the to-be-formed LV PMOS transistor, a LV n-well 624-2 of the base region of the to-be-formed pnp transistor, and a LV n-well 624-3 of the collector region of the to-be-formed npn transistor. Mask 622 is then removed.

In accordance with the present invention, as shown in FIG. 6D, the LV n-wells 624-2 and 624-3 are shallower than the LV n-well 624-1 because the dopant for the LV n-wells 624-2 and 624-3 must pass through first polysilicon layer 432 and the underlying gate oxide layer 430. As a result, LV n-well 624-2 lies with HV p-well 618, and forms the base of the to-be-formed pnp transistor.

After mask 622 has been removed, as shown in FIG. 6E, a mask 626 is formed and patterned on the top surface of p− semiconductor material 410 and first polysilicon layer 432. Following this, the exposed regions of first polysilicon layer 432 and the underlying gate oxide region 430 are removed and no longer lie over HV p-well 618 (and deep n− wells 416C and 612). Mask 626 is then removed.

As shown in FIG. 6F, once mask 626 has been removed, method 600 next forms mask 442 in FIG. 4G, and then follows the remaining process of method 400 to form the BiCMOS structure shown in FIG. 5. As further shown in FIG. 6F, since first polysilicon layer 432 and gate oxide layer 430 have been removed, the LV p-well 444-3 that corresponds with the collector of the pnp transistor touches HV p-well 618.

Thus, a BiCMOS structure and a method of forming the BiCMOS structure have been disclosed. One of the advantages of the present invention is that the method forms the npn and pnp bipolar transistors in a CMOS process flow. In addition, a further advantage of the present invention is that the collectors of the npn and pnp bipolar transistors can be biased differently than the p-type substrate material.

In other words, HV p-well 618, LV p-well 444-3, and p+ region 492C, which function as the collector of the pnp transistor (LV n-well 624-2 and p+ region 492E function as the base and emitter, respectively, of the pnp transistor) are separated from p− semiconductor material 410 by deep n− well 612, thereby allowing the p-type collector to be biased differently from p− semiconductor material 410. Further, deep n− well 416C, LV n-well 624-3, and n+ region 484C, which function as the collector of the npn transistor (LV p-well 444-2 and n+ region 484E function as the base and emitter, respectively, of the npn transistor) can be biased differently from p− semiconductor material 410.

It should be understood that the above descriptions are examples of the present invention, and that various alternatives of the invention described herein may be employed in practicing the invention. Thus, it is intended that the following claims define the scope of the invention and that structures and methods within the scope of these claims and their equivalents be covered thereby.

What is claimed is:

1. A semiconductor structure comprising:
a semiconductor material of a first conductivity type;
a first well of a second conductivity type touching the semiconductor material;
a second well of the first conductivity type touching and lying directly above the first well;
a third well of the second conductivity type touching and lying directly above the second well;
an emitter region of the first conductivity type touching the third well;
a fourth well of the first conductivity type lying above the first well, the second and fourth wells having substantially equal dopant concentrations; and
spaced-apart source and drain regions of the second conductivity type that touch the fourth well.

2. The semiconductor structure of claim 1 wherein the second well is spaced apart from the semiconductor material.

3. The semiconductor structure of claim 2 wherein the second and fourth wells are spaced apart.

4. The semiconductor structure of claim 3 wherein the fourth well is spaced apart from the semiconductor material.

5. The semiconductor structure of claim 4 and further comprising:
a fifth well of the second conductivity type that touches the semiconductor material; and
spaced-apart source and drain regions of the first conductivity type that touch the fifth well.

6. The semiconductor structure of claim 5 wherein the third and fifth wells have substantially equal dopant concentrations.

7. The semiconductor structure of claim 6 and further comprising:
a sixth well of the first conductivity type that lies above the first well; and
spaced-apart source and drain regions of the second conductivity type that touch the sixth well.

8. The semiconductor structure of claim 7 wherein the fourth well and the sixth well have different dopant concentrations.

9. The semiconductor structure of claim 8 wherein the sixth well is spaced apart from the semiconductor material.

10. The semiconductor structure of claim 9 and further comprising a collector region of the first conductivity type, the collector region touching and lying directly above the first well, and touching the second well.

11. A semiconductor structure comprising:
a semiconductor material of a first conductivity type;
a first well of a second conductivity type touching the semiconductor material;
a second well of the first conductivity type touching and lying above the first well;
a third well of the second conductivity type touching and lying above the second well;
an emitter region of the first conductivity type touching the third well;
a fourth well of the first conductivity type lying above the first well, the second and fourth wells having different dopant concentrations; and
an emitter region of the second conductivity type touching the fourth well.

12. The semiconductor structure of claim 11 wherein the second well is spaced apart from the semiconductor material.

13. The semiconductor structure of claim 12 and further comprising:
a fifth well of the first conductivity type lying above the first well, the second and fifth wells having substantially equal dopant concentrations; and
spaced-apart source and drain regions of the second conductivity type that touch the fifth well.

14. The semiconductor structure of claim 13 and further comprising:
a sixth well of the second conductivity type that touches the semiconductor material; and
spaced-apart source and drain regions of the first conductivity type that touch the sixth well.

15. The semiconductor structure of claim 14 wherein the third and sixth wells have substantially equal dopant concentrations.

16. A method of forming a semiconductor structure in a semiconductor material of a first conductivity type comprising:
forming a first well of a second conductivity type to touch the semiconductor material;
simultaneously forming a second well and a third well of the first conductivity type, the second well touching and lying directly above the first well, the second and third wells having substantially equal dopant concentrations;
forming a fourth well of the second conductivity type to touch and lie directly above the second well;
forming an emitter region of the first conductivity type to touch the fourth well; and
forming spaced-apart source and drain regions of the second conductivity type to touch the third well.

17. The method of claim 16 wherein the second well is spaced apart from the semiconductor material.

18. The method of claim 17 wherein the second and third wells are spaced apart.

19. The method of claim 18 wherein the third well is spaced apart from the semiconductor material.

20. The method of claim 19 and further comprising:
forming a fifth well of the second conductivity type simultaneously with the fourth well, the fifth well touching the semiconductor material, the fourth and fifth wells having substantially equal dopant concentrations; and
forming spaced-apart source and drain regions of the first conductivity type to touch the fifth well.
